(19) United States
(12) Patent Application Publication
(10) Pub. No.: US 2025/0088774 A1
(43) Pub. Date: Mar. 13, 2025

(54) RAMP GENERATION CIRCUIT, IMAGE SENSING DEVICE INCLUDING THE RAMP GENERATION CIRCUIT, AND METHOD FOR OPERATING THE IMAGE SENSING DEVICE

(71) Applicant: SK hynix Inc., Gyeonggi-do (KR)

(72) Inventors: Han Sol PARK, Gyeonggi-do (KR); Shin Hoo KIM, Gyeonggi-do (KR); Yu Jin PARK, Gyeonggi-do (KR)

(21) Appl. No.: 18/818,613

(22) Filed: Aug. 29, 2024

(30) Foreign Application Priority Data
Sep. 8, 2023 (KR) 10-2023-0119512

(51) Int. Cl. H04N 25/78; H04N 25/77

(52) U.S. Cl. CPC H04N 25/78; H04N 25/77

(57) ABSTRACT

A ramp generation circuit includes a ramping voltage generator configured to generate a ramping voltage that changes depending on a first slope or a second slope, a blocking capacitor configured to transmit the ramping voltage to a transfer node, a signal output unit configured to amplify a voltage of the transfer node and to output a ramp output signal to an output node, and a ramp switch configured to selectively connect the transfer node to the output node.

### CROSS-REFERENCE TO RELATED APPLICATION

This patent application claims the priority and benefits of Korean patent application No. 10-2023-0119512, filed on Sep. 8,2023, the disclosure of which is incorporated herein by reference in its entirety.

### TECHNICAL FIELD

The technology and embodiments of the present disclosure generally relate to a ramp generation circuit capable of generating a high dynamic range (HDR) image, an image sensing device including the ramp generation circuit, and a method for operating the image sensing device.

### BACKGROUND

An image sensing device is a device for capturing optical images by converting light into electrical signals using a photosensitive semiconductor material which reacts to light. With the development of the automotive, medical, computer and communication industries, the demand for high-performance image sensing devices has been increasing in various fields such as smart phones, wearable smart devices, digital cameras, game machines, IoT (Internet of Things), robots, surveillance cameras and medical micro cameras.

Recently, in order to provide high-quality images, interest in HDR images is rapidly increasing, and various techniques capable of acquiring HDR images are being developed. Among such techniques, technology for varying an analog gain that is used to convert an electrical signal indicating the intensity of an incident light into digital data can contribute to obtaining HDR images, but there is an issue in that much more resources are consumed for hardware implementation for acquiring such HDR images.

### SUMMARY

In accordance with an embodiment of the present disclosure, a ramp generation circuit may include a ramping voltage generator configured to generate a ramping voltage that changes depending on a first slope or a second slope, a blocking capacitor configured to transmit the ramping voltage to a transfer node, a signal output unit configured to amplify a voltage of the transfer node and to output a ramp output signal to an output node, and a ramp switch configured to selectively connect the transfer node to the output node.

In accordance with another embodiment of the present disclosure, an image sensing device may include a ramp generation circuit including not only a ramp source follower transistor configured to amplify a voltage of a transfer node to which a ramping voltage that changes depending on a first slope or a second slope is applied and to output a ramp output signal to an output node, but also a ramp switch configured to selectively connect the transfer node to the output node, and an analog-to-digital converter (ADC) configured to generate image data by comparing the ramp output signal with a pixel signal being output from a pixel that senses incident light.

In accordance with another embodiment of the present disclosure, a method for operating an image sensing device may include generating first image data by comparing a ramp output signal changing with a first slope with a pixel signal being output from a pixel that senses incident light, electrically connecting an output node through which the ramp output signal is output to a gate of a ramp source follower transistor configured to generate the ramp output signal, and generating second image data by comparing the ramp output signal changing with a second slope different from the first slope with the pixel signal.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an imaging device based on some embodiments of the present disclosure.

FIG. 2 is a circuit diagram illustrating a pixel included in a pixel array of FIG. 1 based on some embodiments of the present disclosure.

FIG. 3 is a graph illustrating a relationship between illuminance and each of a response generated with a high analog gain and a response generated with a low analog gain based on some embodiments of the present disclosure.

FIG. 4 is a circuit diagram illustrating an analog-to-digital converter (ADC) shown in FIG. 1 based on some embodiments of the present disclosure.

FIG. 5 is a circuit diagram illustrating a ramp generator as shown in FIG. 4 based on some embodiments of the present disclosure.

FIG. 6 is a timing diagram illustrating an operation of converting a pixel signal into image data by the ADC shown in FIG. 2 based on some embodiments of the present disclosure.

### DETAILED DESCRIPTION

The present disclosure provides embodiments and examples of a ramp generation circuit capable of generating a high dynamic range (HDR) image, an image sensing device including the ramp generation circuit, and a method for operating the image sensing device, that may be used in configurations to substantially address one or more technical or engineering issues and to mitigate limitations or disadvantages encountered in some other image sensing devices. Some embodiments of the present disclosure relate to a ramp generation circuit capable of generating a high dynamic range (HDR) image with relatively simplified hardware, an image sensing device including the ramp generation circuit, and a method for operating the image sensing device. In recognition of the issues above, the ramp generation circuit, the image sensing device including the ramp generation circuit, and the method for operating the image sensing device based on some embodiments of the present disclosure can reduce the circuit area and power consumption required to implement the ramp generator configured to use a plurality of analog gains.

Reference will now be made in detail to the embodiments of the present disclosure, examples of which are illustrated in the accompanying drawings. Wherever possible, the same reference numbers will be used throughout the drawings to refer to the same or like parts. While this disclosure is susceptible to various modifications and alternative forms, specific embodiments thereof are shown by way of example in the drawings. However, this disclosure should not be construed as being limited to the embodiments set forth herein.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the present disclosure may provide a variety of effects capable of being directly or indirectly recognized through the disclosed technology.

Various embodiments of the present disclosure relate to a ramp generation circuit capable of generating a high dynamic range (HDR) image with relatively simplified hardware, an image sensing device including the ramp generation circuit, and a method for operating the image sensing device.

It is to be understood that both the foregoing general description and the following detailed description of the disclosed technology are illustrative and descriptive, and are intended to provide further description of the embodiments of the present disclosure as claimed.

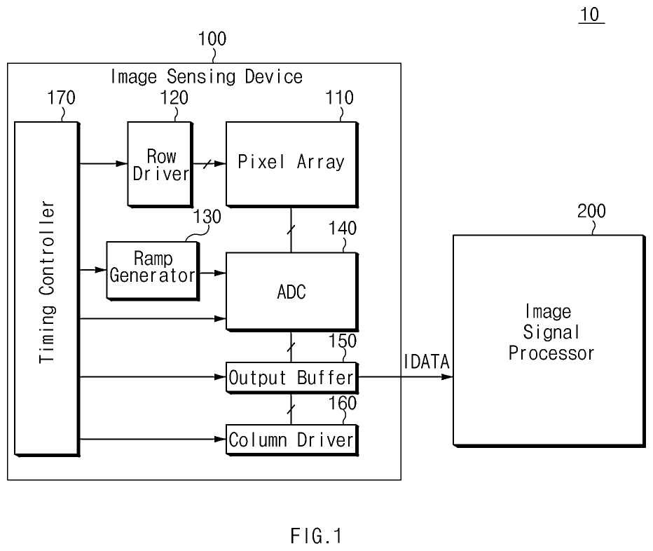

FIG. 1 is a block diagram illustrating an imaging device 10 based on some embodiments of the present disclosure.

Referring to FIG. 1, the imaging device 10 may refer to a device, for example, a digital still camera for photographing still images or a digital video camera for photographing moving images. For example, the imaging device 10 may be implemented as a Digital Single Lens Reflex (DSLR) camera, a mirrorless camera, or a smartphone, and others. The imaging device 10 may include a device having both a lens and an image pickup element such that the device can capture (or photograph) a target object and can thus create an image of the target object.

The imaging device 10 may include an image sensing device 100 and an image signal processor (ISP) 200.

The image sensing device 100 may be a complementary metal oxide semiconductor image sensor (CIS) for converting incident light into an electrical signal. The image sensing device 100 may include a pixel array 110, a row driver 120, a ramp generator 130, an analog-to-digital converter (ADC) 140, an output buffer 150, a column driver 160, and a timing controller 170. The components of the image sensing device 100 illustrated in FIG. 1 are discussed by way of example only, and embodiments of the present disclosure may encompass numerous other changes, substitutions, variations, alterations, and modifications.

The pixel array 110 may include a plurality of imaging pixels arranged in rows and columns. In one example, the plurality of imaging pixels can be arranged in a two-dimensional (2D) pixel array including rows and columns. In another example, the plurality of imaging pixels can be arranged in a three-dimensional (3D) pixel array. The plurality of imaging pixels may convert an optical signal into an electrical signal on a unit pixel basis or a pixel group basis, where pixels in a pixel group share at least certain internal circuitry. The pixel array 110 may receive driving signals, including a row selection signal, a pixel reset signal and a transfer signal, from the row driver 120. Upon receiving the driving signal, corresponding imaging pixels in the pixel array 110 may be activated to perform the operations corresponding to the row selection signal, the pixel reset signal, and the transfer signal.

The row driver 120 may activate the pixel array 110 to perform certain operations on the imaging pixels in the corresponding row based on commands and control signals provided by controller circuitry such as the timing controller 170. In some embodiments, the row driver 120 may select one or more imaging pixels arranged in one or more rows of the pixel array 110. The row driver 120 may generate a row selection signal to select one or more rows among the plurality of rows. The row driver 120 may sequentially enable the pixel reset signal for resetting imaging pixels corresponding to at least one selected row, and the transfer signal for the pixels corresponding to the at least one selected row. Thus, a reference signal and an image signal, which are analog signals generated by each of the imaging pixels of the selected row, may be sequentially transferred to the ADC 140. The reference signal may be an electrical signal that is provided to the ADC 140 in a state that a sensing node of an imaging pixel (e.g., floating diffusion node) is reset, and the image signal may be an electrical signal that is provided to the ADC 140 in a state that photocharges generated by the imaging pixel are accumulated in the sensing node. The reference signal indicating a reset noise of individual pixel and the image signal indicating the intensity of the incident light (hereinafter, simply referred to as the “incident intensity”) may be generically called a pixel signal as necessary.

CMOS image sensors may use the correlated double sampling (CDS) to remove undesired offset values of pixels known as the fixed pattern noise by sampling a pixel signal twice to remove the difference between these two samples. In one example, the correlated double sampling (CDS) may remove the undesired offset value of pixels by comparing pixel output voltages obtained d before and after photocharges generated by the incident light are accumulated in the sensing node so that only pixel output voltages based on the incident light can be measured. In some embodiments of the present disclosure, the ADC 140 may sequentially sample and hold voltage levels of the reference signal and the image signal, which are provided to each of a plurality of column lines from the pixel array 110. That is, the ADC 140 may sample and hold the voltage levels of the reference signal and the image signal which correspond to each of the columns of the pixel array 110.

The ramp generator 130 may generate a ramp signal required for an analog-to-digital conversion (ADC) operation of the ADC 140 under control of the timing controller 170, and may supply the generated ramp signal to the ADC 140. The ramp generator 130 may also be referred to as a ramp generation circuit.

The ADC 140 may sample and hold the pixel signal for each column upon receiving the pixel signal from each column line of the pixel array 110, may convert the resultant signal into digital signals, and may output the digital signals. In some embodiments, the ADC 140 may be implemented as a ramp-compare type ADC configured to use a ramp output signal of the ramp generator 130. The ramp-compare type ADC may include a comparator circuit for comparing the analog pixel signal with a ramp signal that ramps up or down according to time, and a timer (or counter) for performing counting until a voltage of the ramp signal matches the analog pixel signal.

Image data (IDATA) generated by the ADC 140 may correspond to at least two different sensitivities. Here, the sensitivity may mean an increase in amount of image data IDATA (or an increase amount of a response) with respect to an increase in amount of the incident intensity. That is, as the sensitivity increases, the amount of increase in image data IDATA increases in response to an increase in the incident intensity. As the sensitivity decreases, the amount of increase in image data IDATA decreases in response to an increase in the incident intensity. In some embodiments, the sensitivity may be determined by an analog gain. The analog gain may refer to a ratio of a voltage level of an analog pixel signal, which varies according to the incident intensity, to the size of image data (IDATA).

The output buffer 150 may temporarily hold the column-based image data (i.e., data (IDATA) obtained by analog-to-digital conversion of the pixel signal) provided from the ADC 140 to output the image data. In one embodiment, the image data provided to the output buffer 150 from the ADC 140 may be temporarily stored in the output buffer 150 based on control signals of the timing controller 170. The output buffer 150 may provide an interface to compensate for data rate differences or transmission rate differences between the image sensing device 100 and other devices.

The column driver 160 may select a column of the output buffer upon receiving a control signal from the timing controller 170, and may sequentially output the image data (IDATA), which are temporarily stored in the selected column of the output buffer 150. In some embodiments, upon receiving an address signal from the timing controller 170, the column driver 160 may generate a column selection signal based on the address signal, and may select a column of the output buffer 150, thereby outputting the image data (IDATA) as an output signal from the selected column of the output buffer 150.

The timing controller 170 may control operations of the row driver 120, the ramp generator 130, the ADC 140, the output buffer 150, and the column driver 160.

The timing controller 170 may provide the row driver 120, the ramp generator 130, the ADC 140, the output buffer 150, and the column driver 160 with a clock signal required for the operations of the respective components of the image sensing device 100, a control signal for timing control, and address signals for selecting a row or column. In an embodiment, the timing controller 170 may include a logic control circuit, a phase lock loop (PLL) circuit, a timing control circuit, a communication interface circuit and others.

The image signal processor (ISP) 200 may perform image processing of image data received from the image sensing device 100. The image signal processor (ISP) 200 may reduce noise of image data, and may perform various types of image signal processing (e.g. interpolation, synthesis, gamma correction, color filter array interpolation, color matrix, color correction, color enhancement, lens distortion correction, etc.) for image-quality improvement of the image data. In addition, the image signal processor (ISP) 200 may compress image data that has been created by execution of image signal processing for image-quality improvement, such that the image signal processor (ISP) 200 can create an image file using the compressed image data. Alternatively, the image signal processor (ISP) 200 may recover image data from the image file. In this case, the scheme for compressing such image data may be a reversible format or an irreversible format. As a representative example of such compression format, in the case of using a still image, Joint Photographic Experts Group (JPEG) format, JPEG 2000 format, or the like can be used. In addition, in the case of using moving images, a plurality of frames can be compressed according to Moving Picture Experts Group (MPEG) standards such that moving image files can be created. For example, the image files may be created according to Exchangeable image file format (Exif) standards.

The image signal processor (ISP) 200 may generate an HDR image by synthesizing at least two images having different sensitivities. For example, the image sensing device 100 may output a low-sensitivity image generated by a low analog gain having a relatively lower sensitivity and a high-sensitivity image generated by a high analog gain having a relatively higher sensitivity. The image signal processor (ISP) 200 may combine the low-sensitivity image and the high-sensitivity image, resulting in formation of an HDR image. Here, the low-sensitivity and the high-sensitivity may correspond to relative concepts, the image sensing device 100 may generate image data (IDATA) having at least N different sensitivities, where N is an integer of 2 or more, and the image sensing processor 200 may generate the HDR image using the resultant image data (IDATA).

The image signal processor (ISP) 200 may transmit the ISP image data to a host device (not shown). The host device (not shown) may be a processor (e.g. an application processor) for processing the ISP image data received from the image signal processor (ISP) 200, a memory (e.g. a non-volatile memory) for storing the ISP image data, or a display device (e.g. a liquid crystal display (LCD)) for visually displaying the ISP image data.

In addition, the image signal processor (ISP) 200 may transmit a control signal for controlling operations (e.g. whether or not to operate, an operation timing, an operation mode, etc.) of the image sensing device 100 to the image sensing device 100.

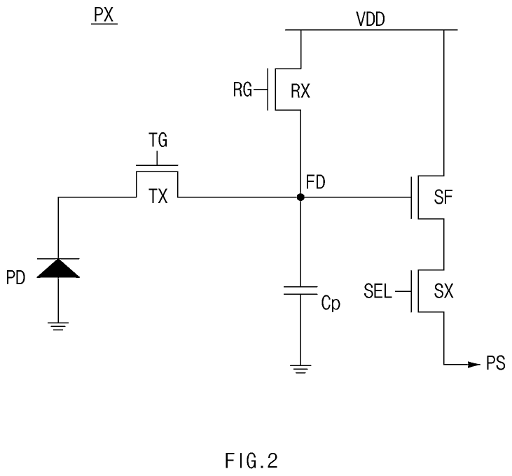

FIG. 2 is a circuit diagram illustrating a pixel (PX) included in the pixel array 110 of FIG. 1 based on some embodiments of the present disclosure.

Referring to FIG. 2, the pixel (PX) may be one of a plurality of pixels included in the pixel array 110. Although FIG. 2 shows only one pixel (PX) for convenience of description, other embodiments are also possible, and it should be noted that other pixels may also have substantially the same structure and operations as in the pixel (PX) without departing from the scope or spirit of the present disclosure.

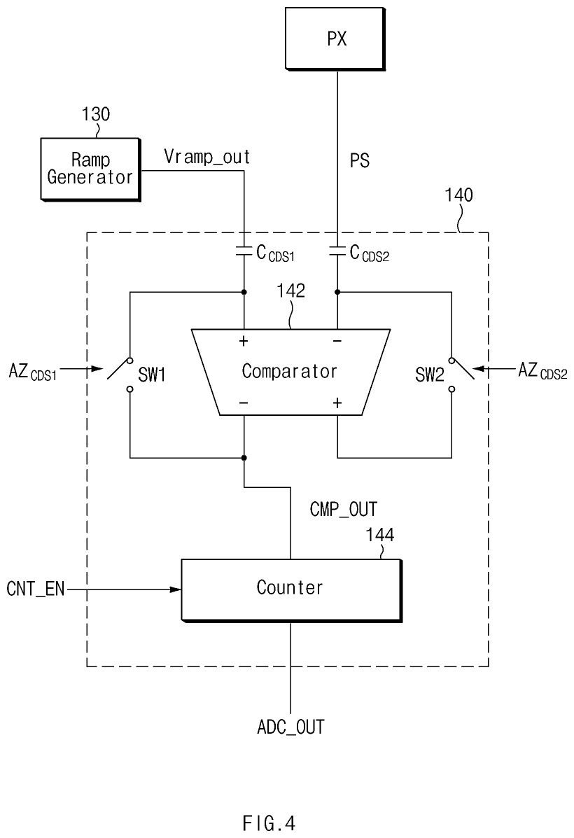

The pixel (PX) may include a photoelectric conversion element (PD), a transfer transistor (TX), a reset transistor (RX), a floating diffusion region (FD), a pixel capacitor (Cₚ), a source follower transistor (SF), and a selection transistor (SX). Although FIG. 4 shows that the pixel (PX) includes only one photoelectric conversion element (PD), other embodiments are also possible, and it should be noted that the pixel (PX) can also be a shared pixel including a plurality of photoelectric conversion elements. In this case, the plurality of transfer transistors may be provided to correspond to the photoelectric conversion elements, respectively.

Each of the photoelectric conversion elements (PDs) may generate and accumulate photocharges corresponding to the incident intensity. For example, each of the photoelectric conversion elements (PDs) may be implemented as a photodiode, a phototransistor, a photogate, a pinned photodiode, or a combination thereof.

If the photoelectric conversion element (PD) is implemented as a photodiode, the photoelectric conversion element (PD) may be a region that is doped with second conductive impurities (e.g., N-type impurities) in a substrate including first conductive impurities (e.g., P-type impurities).

The transfer transistor (TX) may be coupled between the photoelectric conversion element (PD) and the floating diffusion region (FD). The transfer transistor (TX) may be turned on or off in response to a transfer signal (TG). If the transfer transistor (TX) is turned on by a transfer signal (TG) of a logic high level, photocharges accumulated in the corresponding photoelectric conversion element (PD) can be transmitted to the floating diffusion region (FD).

The reset transistor (RX) may be disposed between the floating diffusion region (FD) and the power-supply voltage (VDD), and the voltage of the floating diffusion region (FD) can be reset to the power-supply voltage (VDD) in response to a reset control signal (RG).

The floating diffusion region (FD) may accumulate photocharges received from the transfer transistor (TX). The floating diffusion region (FD) can be coupled to the pixel capacitor (Cₚ) connected to a ground terminal. For example, the floating diffusion region (FD) may be a region that is doped with second conductive impurities (e.g., N-type impurities) in a substrate (e.g., a P-type substrate) including first conductive impurities. In this case, the substrate and the impurity doped region can be modeled as the pixel capacitor (Cₚ) acting as a junction capacitor. The floating diffusion region (FD) may be referred to as a sensing node.

In some embodiments, a logic high level may mean a voltage level for activating (e.g., turning on) a corresponding element (e.g., a transistor), and a logic low level may mean a voltage level for deactivating (e.g., turning off) a corresponding element (e.g., a transistor).

Although FIG. 2 shows a case in which the floating diffusion region (FD) having only one capacitance is used for convenience of description, other embodiments are also possible, and the floating diffusion region (FD) may also have two or more capacitances. For example, the floating diffusion region (FD) may selectively receive additional capacitance by connecting to a dual conversion gain (DCG) transistor, so that the floating diffusion region (FD) may have two capacitances.

The source follower transistor (SF) may be coupled between the selection transistor (SX) and the power-supply voltage (VDD), may amplify a change in electrical potential of the floating diffusion region (FD) that has received photocharges accumulated in the photoelectric conversion element (PD), and may transmit the amplified result to the selection transistor (SX).

The selection transistor (SX) may be coupled between the source follower transistor (SF) and the output signal line, and may be turned on by the selection control signal (SEL), so that the selection transistor (SX) can output the electrical signal received from the source follower transistor (SF) as the pixel signal (PS).

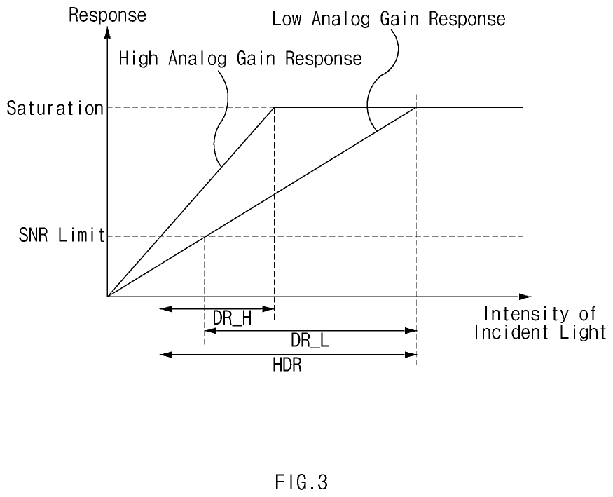

FIG. 3 is a graph illustrating a relationship between illuminance and each of a response generated with a high analog gain and a response generated with a low analog gain based on some embodiments of the present disclosure.

Referring to FIG. 3, image data generated by the ADC 140 having a high analog gain may be defined as a high analog gain (HAG) response, and image data generated by the ADC 140 having a low analog gain may be defined as a low analog gain (LAG) response. FIG. 3 illustrates a high analog gain (HAG) response having a relatively larger amount of increase in response according to an increase in the incident intensity and a low analog gain (LAG) response having a relatively smaller amount of increase in response according to an increase in the incident intensity. As can be seen from FIG. 3, each of the HAG response and the LAG response is a function of the incident intensity (the “intensity of incident light”) applied to the corresponding pixel. Here, the response may refer to image data (IDATA) of the corresponding pixel.

In this case, the response may have a signal-to-noise ratio (SNR) limit (i.e. an SNR threshold level) and a saturation level.

The signal-to-noise ratio (SNR) threshold level may refer to a threshold value that can satisfy a reference SNR that is predetermined. A response less than the SNR threshold level may be treated as an invalid response not satisfying the reference SNR, and a response greater than the SNR threshold level may be treated as a valid response satisfying the reference SNR. The reference SNR may be determined experimentally in consideration of characteristics of the image sensing device 100.

A saturation level may refer to a maximum level that indicates the incident intensity. The saturation level may be determined by the capability (e.g., capacitance of a photoelectric conversion element) by which the pixel can convert the incident intensity into photocharges, the capability (e.g., capacitance of a floating diffusion region (FD)) by which photocharges can be converted into analog signals, and the capability (e.g., an input range of the ADC) by which analog signals can be converted into digital signals. As the incident intensity increases, the response may increase in proportion to the incident intensity until the response reaches the saturation level. After the response reaches the saturation level, the response may not increase although the incident intensity increases. For example, after the response reaches the saturation level, the response may have the same value as the saturation value and not increase above the saturation level.

The valid response of each pixel may refer to a response that can indicate the incident intensity while satisfying the reference SNR. The range of the incident intensity corresponding to the valid response of a pixel may be referred to as a dynamic range of the pixel. That is, the dynamic range of the pixel may refer to the incident-light intensity range in which each pixel has a valid response.

The HAG response may provide the response having a relatively large increase in response to an increase in the incident intensity. Thus, the HAG response may have a relatively greater slope in response to the increase of the incident intensity until the response reaches the saturation level and have a fixed level corresponding to the saturation level regardless of the increase in the incident intensity after the response reaches the saturation level.

The LAG response may provide the response having a relatively small increase in response to an increase in the incident intensity. Thus, the LAG response may increase with a relatively smaller slope in response to the increase of the incident intensity until the response reaches the saturation level, and has a fixed level corresponding to the saturation level regardless of the increase in the incident intensity after the response reaches the saturation level.

As illustrated in FIG. 3, a minimum value of an HAG-response dynamic range (DR_H) (or a first dynamic range) may be less than a minimum value of an LAG-response dynamic range (DR_L) (or a second dynamic range), and a maximum value of the HAG-response dynamic range (DR_H) may be less than a maximum value of the LAG-response dynamic range (DR_L). Therefore, in a low-illuminance range in which the incident intensity is relatively small, the HAG response may be more suitably used to indicate the incident intensity. In a high-illuminance range in which the incident intensity is relatively large, the LAG response may be more suitably used to indicate the incident intensity.

A high dynamic range (HDR) image can be implemented using both the HAG response suitable for the low-illuminance range and the LAG response suitable for the high-illuminance range. To this end, at least a portion of the HAG-response dynamic range and at least a portion of the LAG-response dynamic range may overlap each other.

A method for forming a high dynamic range (HDR) image may be implemented as a method for synthesizing the HDR image by calculating (e.g., summing) the HAG response and the LAG response, and/or a method for forming a final image based on the HAG-response at a low-illuminance level and forming a final image based on the LAG-response at a high-illuminance level, without being limited thereto.

FIG. 4 is a circuit diagram illustrating an analog-to-digital converter (ADC) 140 based on some embodiments of the present disclosure.

Referring to FIG. 4, the ADC 140 may receive a ramp output signal (V_{ramp_out}) from the ramp generator 130, may receive a pixel signal (PS) from the pixel (PX), and may generate and output ADC data (ADC_OUT) based on the ramp output signal (V_{ramp_out}) and the pixel signal (PS).

The ADC 140 may include a first correlated double sampling (CDS) capacitor (C_{CDS1}), a second CDS capacitor (C_{CDS2}), a comparator 142, a first switch (SW1), a second switch (SW2), and a counter 144.

The first CDS capacitor (C_{CDS1}) may receive the ramp output signal (V_{ramp_out}) from the ramp generator 130, and may transmit the ramp output signal (V_{ramp_out}) to the comparator 142. The second CDS capacitor (C_{CDS2}) may receive the pixel signal (PS) from the pixel (PX), and may transmit the pixel signal (PS) to the comparator 142. The first CDS capacitor (C_{CDS1}) may be referred to as a first input capacitor of the ADC 140, and the second CDS capacitor (CCDS2) may be referred to as a second input capacitor of the ADC 140.

The comparator 142 may compare the ramp output signal (V_{ramp_out}) with the pixel signal (PS), may generate comparison data (CMP_OUT) according to the result of performing a comparison, and may transmit the comparison data (CMP_OUT) to the counter 144. In some embodiments, when the ramp output signal (V_{ramp_out}) is greater than the pixel signal (PS), the comparator 142 may generate comparison data (CMP_OUT) having a logic high level. In addition, when the ramp output signal (V_{ramp_out}) is smaller than the pixel signal (PS), the comparator 142 may generate comparison data (CMP_OUT) having a logic low level. That is, the comparison data (CMP_OUT) may indicate the magnitude relationship between the ramp output signal (V_{ramp_out}) and the pixel signal (PS).

The first switch (SW1) may be opened or closed according to a first CDS auto-zeroing signal (AZ_{CDS1}), and the second switch (SW2) may be opened or closed according to a second CDS auto-zeroing signal (AZ_{CDS1}). The first switch (SW1) having received the first CDS auto-zeroing signal (AZ_{CDS1}) having a logic high level may connect a non-inverting input terminal of the comparator 142 to an inverting output terminal of the comparator 142. In addition, the second switch (SW2) having received the second CDS auto-zeroing signal (AZ_{CDS2}) of a logic high level may connect the inverting input terminal of the comparator 142 to the non-inverting output terminal of the comparator 142. The first and second CDS auto-zeroing signals (AZ_{CDS1}, AZ_{CDS2}) may have a logic high level and a logic low level at the same timing point. The first and second CDS auto-zeroing signals (AZ_{CDS1}, AZ_{CDS2}) may be generated and supplied by the timing controller 170.

As the first switch (SW1) and the second switch (SW2) are closed, the comparator 142 may perform an auto-zeroing operation. Here, the auto-zeroing operation may refer to an operation of adjusting a voltage level of the non-inverting input terminal, to which the ramp output signal (V_{ramp_out}) is input, and a voltage level of the inverting input terminal, to which the pixel signal (PS) is input, for comparing the ramp output signal (V_{ramp_out}) with the pixel signal (PS)

The counter 144 may be activated in response to a counter enable signal (CNT_EN), the activated counter 144 may perform counting in response to the logic high level comparison data (CMP_OUT), and may output the counting result as ADC data (ADC_OUT). Here, the ADC data (ADC_OUT) may correspond to the image data (IDATA) described in FIG. 1.

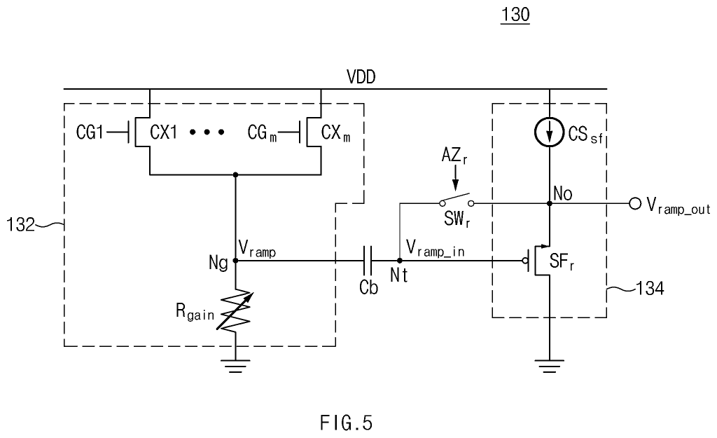

FIG. 5 is a circuit diagram illustrating a ramp generator 130 shown in FIG. 4 based on some embodiments of the present disclosure.

Referring to FIG. 5, the ramp generator 130 may correspond to the ramp generator 130 shown in FIG. 4, and the ramp generator 130 may include a ramping voltage generator 132, a blocking capacitor (C_{b}), a ramp switch (SWᵣ), and a signal output unit 134.

The ramping voltage generator 132 may generate a ramping voltage (Vᵣₐₘₚ) changing according to a first slope or a second slope. Here, the magnitude (or absolute value) of the first slope may be greater than the magnitude (or absolute value) of the second slope. The ramping voltage generator 132 may include a plurality of current transistors (CX1˜CXm) (where ‘m’ is an integer of 2 or greater) and a variable load resistor (R_{gain}).

The plurality of current transistors (CX1˜CXm) may be connected in parallel between the power-supply voltage terminal (VDD) and the variable load resistor (R_{gain}). The plurality of current transistors (CX1˜CXm) may be sequentially turned on or off in response to the corresponding current control signals (CG1˜CGm). The plurality of turned-on current transistors (CX1˜CXm) may generate currents having the same magnitude, respectively. Accordingly, each of the plurality of current transistors (CX1˜CXm) may generate a ramping voltage (Vᵣₐₘₚ) that increases or decreases according to a slope determined by a resistance value of the variable load resistor (R_{gain}). The current control signals (CG1˜CGm) for respectively controlling the plurality of current transistors (CX1˜CXm) may be provided from the timing controller 170. Each of the current control signals (CG1˜CGm) may have a logic high level or a logic low level, and the current transistor to which the current control signal of a logic high level is applied may be turned on, and the current transistor to which the current control signal of a logic low level is applied may be turned off.

In FIG. 5, although each of the plurality of current transistors (CX1˜CXm) is illustrated as an NMOS transistor, other embodiments are also possible, and each of the plurality of current transistors (CX1˜CXm) may also be implemented as a PMOS transistor.

The variable load resistor (R_{gain}) may generate a ramping voltage (Vᵣₐₘₚ) upon receiving currents from the plurality of current transistors (CX1˜CXm). In some embodiments, the variable load resistor (R_{gain}) may have a first resistance value in a low analog gain (LAG) mode, and may have a second resistance value in a high analog gain (HAG) mode. For example, the first resistance value may be greater than the second resistance value, so that a slope of the ramping voltage (Vᵣₐₘₚ) in the LAG mode may be greater than a slope of the ramping voltage (Vᵣₐₘₚ) in the HAG mode. In some embodiments, the resistance value of the variable load resistor (V_{gain}) may be controlled by the timing controller 170.

The blocking capacitor (C_{b}) may be connected between a generation node (N_{g}) at which the ramping voltage (Vᵣₐₘₚ) is generated and a transfer node (Nₜ) corresponding to an input node of the signal output unit 134. The blocking capacitor (C_{b}) may transmit, to the transfer node (Nₜ), only an alternating current (AC) component of the ramping voltage (Vᵣₐₘₚ) other than a direct current (DC) component of the ramping voltage (Vᵣₐₘₚ). Here, the AC component may refer to a component indicating a change in the ramping voltage (Vᵣₐₘₚ). The blocking capacitor (C_{b}) may transmit the AC component of the ramping voltage (Vᵣₐₘₚ) to the transfer node (Nₜ) without transmitting the DC component of the ramping voltage (Vᵣₐₘₚ) to the transfer node (Nₜ). Here, this AC component of the ramping voltage (Vᵣₐₘₚ) may appear as a ramp input signal (V_{ramp_in}).

The ramp switch (SWᵣ) may be connected between the transfer node (Nₜ) and the output node (Nₒ) through which the ramp output signal (V_{ramp_out}) is output. Since the transfer node (Nₜ) corresponds to a gate of a ramp source follower transistor (SFᵣ) and the output node (Nₒ) corresponds to a source of the ramp source follower transistor (SFᵣ), the ramp switch (SWᵣ) may be connected between the gate and the source of the ramp source follower transistor (SWᵣ). The ramp switch (SWᵣ) may be opened and/or closed in response to a ramp auto-zeroing signal (AZᵣ). The ramp switch (SWᵣ) having received the auto-zeroing signal (AZᵣ) of a logic high level may electrically connect the transfer node (Nₜ) to the output node (Nₒ). The ramp switch (SWᵣ) having received the ramp auto-zeroing signal (AZᵣ) of a logic low level may electrically separate the transfer node (Nₜ) and the output node (Nₒ) from each other. The ramp auto-zeroing signal (AZᵣ) may be generated and supplied by the timing controller 170.

The ramp auto-zeroing signal (AZᵣ) may have a logic high level before the slope of the ramping voltage (Vᵣₐₘₚ) or the ramp output signal (V_{ramp_out}) changes from a specific slope (e.g., the first slope) to another slope (e.g., the second slope) different from the specific slope. That is, the ramp auto-zeroing signal (AZᵣ) may have a logic high level before the slope of the ramping voltage (Vᵣₐₘₚ) or the ramp output signal (V_{ramp_out}) changes.

The signal output unit 134 may include the ramp source follower transistor (SFᵣ) and a source follower current source (CS_{sf}).

The ramp source follower transistor (SFᵣ) may be connected between the source follower current source (CS_{sf}) and the ground terminal, and may generate a ramp output signal (V_{ramp_out}) by amplifying a change in a ramp input signal (V_{ramp_in}) indicating a voltage of the transfer node (Nₜ). That is, the gate of the ramp source follower transistor (SFᵣ) may be connected to the transfer node (Nₜ), the source of the ramp source follower transistor (SFᵣ) may be connected to the output node (Nₒ), and the drain of the ramp source follower transistor (SFᵣ) may be connected to the ground terminal. The ramp source follower transistor (SFᵣ) may be implemented as a P-channel MOSFET (PMOS) transistor as shown in FIG. 5, but the scope of the present disclosure is not limited thereto, and may also be implemented as an N-channel MOSFET (NMOS) transistor according to another embodiment. However, in this case, the source-follower current source (CS_{sf}) may be connected to the ground terminal instead of the power-supply voltage terminal (VDD).

The source follower current source (CS_{sf}) may be connected between the power-supply voltage terminal (VDD) and the ramp source follower transistor (SFᵣ) (or the output node Nₒ). The source follower current source (CS_{sf}) may control the current flowing through the ramp source follower transistor (SFᵣ) such that the ramp output signal (V_{ramp_out}) has linearity with respect to the ramp input signal (V_{ramp_in}).

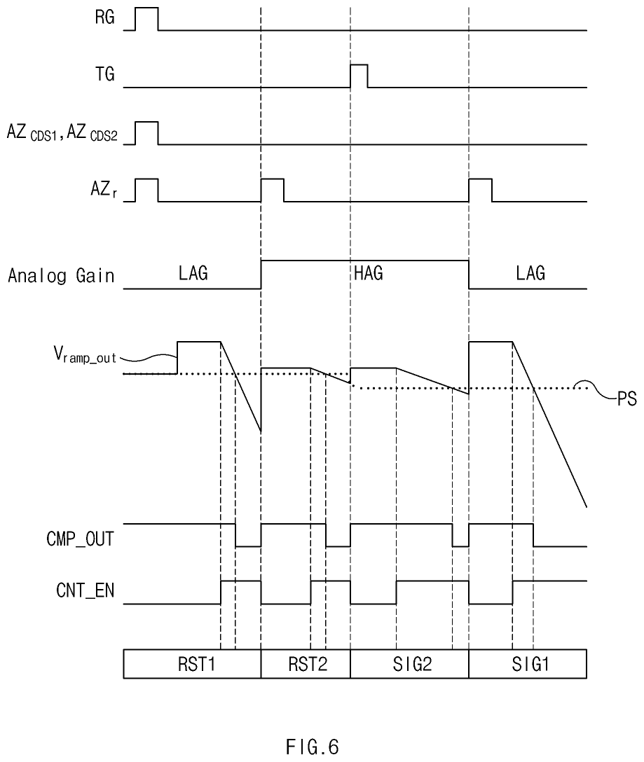

FIG. 6 is a timing diagram illustrating an operation of converting a pixel signal into image data by the ADC 140 shown in FIG. 2 based on some embodiments of the present disclosure.

Referring to FIG. 6, the operation of converting a pixel signal into image data may be performed while being divided into a first reset period (RST1), a second reset period (RST2), a second signal period (SIG2), and a first signal period (SIG1). The first reset period (RST1) may refer to a period in which a reference signal of the pixel (PX) is AD (analog-to-digital)-converted in the LAG mode, and the second reset period (RST12) may refer to a period in which a reference signal of the pixel (PX) is AD-converted in the LAG mode. The second signal period (SIG2) may refer to a period in which the image signal of the pixel (PX) is AD-converted in the HAG mode, and the first signal period (SIG1) may refer to a period in which the image signal of the pixel (PX) is AD-converted in the LAG mode.

The LAG mode may refer to a mode that uses the ramp output signal (V_{ramp_out}) having a large slope so that the amount of increase in response (or image data) in proportion to the increasing incident intensity can relatively decrease. The HAG mode may refer to a mode that uses the ramp output signal (V_{ramp_out}) having a small slope so that the amount of increase in response (or image data) in proportion to the increasing incident intensity can relatively increase.

In the first reset period (RST1), as the pixel reset signal (RG) temporarily has a logic high level, the pixel signal (PS) corresponding to the voltage of the reset floating diffusion region (FD) may be output from the pixel (PX).

While the first and second CDS auto-zeroing signals (AZ_{CDS1}, AZ_{CDS2}) have a logic high level, the comparator 142 may perform an auto-zeroing operation between the ramp output signal (V_{ramp_out}) and the pixel signal (PS).

While the ramp auto-zeroing signal (AZᵣ) has a logic high level, the ramp generator 130 may perform the auto-zeroing operation on the ramp output signal (V_{ramp_out}). In more detail, the ramp generator 130 may perform the auto-zeroing operation in which the ramp switch (SWᵣ) is closed by the ramp auto-zeroing signal (AZᵣ) having a logic high level and a voltage level of the output node (Nₒ) is then adjusted to a voltage level of the transfer node (Nₜ).

After a predetermined time has elapsed, under control of the timing controller 170, the ramp generator 130 may output the ramp output signal (V_{ramp_out}) decreasing with a first negative (−) slope from a voltage increased by a ramp offset from an auto-zeroing completed level. Here, the ramp offset may be related to characteristics of the ramp generator 130 and may be a variance of a voltage level from the auto-zeroing completed level.

The comparison data (CMP_OUT) may have a logic high level in a period in which the ramp output signal (V_{ramp_out}) is greater than the pixel signal (PS), and may have a logic low level in a period in which the ramp output signal (V_{ramp_out}) is less than the pixel signal (PS).

The counter enable signal (CNT_EN) may have a logic high level in a period in which the ramp output signal (V_{ramp_out}) has a first negative (−) slope. The counter 144 may be activated in response to the counter enable signal (CNT_EN) having a logic high level, and the activated counter 144 may perform counting in a period in which the comparison data (CMP_OUT) has a logic high level, and may output a first reference value indicating the counting result as ADC data (ADC_OUT).

The first reference value may be a digital value obtained when the pixel signal (PS) corresponding to a reference signal is AD-converted in the LAG mode.

In the second reset period (RST2), while the ramp auto-zeroing signal (AZᵣ) has a logic high level, the ramp generator 130 may perform the auto-zeroing operation on the ramp output signal (V_{ramp_out}). Specifically, the ramp generator 130 may perform the auto-zeroing operation in which the ramp switch (SWᵣ) is closed by the ramp auto-zeroing signal (AZᵣ) having a logic high level and the voltage level of the output node (Nₒ) is then adjusted to the voltage level of the transfer node (Nₜ).

In the first reset period (RST1), the ramp output signal (V_{ramp_out}) having a first slope may be generated as the ramping voltage (Vᵣₐₘₚ) having the first slope is generated, only the AC component of the ramping voltage (Vᵣₐₘₚ) is selectively transmitted to the transfer node (Nₜ) by the blocking capacitor (C_{b}) and the change in voltage of the transfer node (Nₜ) is amplified. That is, the transfer node (Vₜ) may have a voltage (e.g., a voltage higher than the DC voltage of the ramping voltage Vᵣₐₘₚ) independent of the DC voltage (or the DC component) of the ramping voltage (Vᵣₐₘₚ), and the voltage level of the output node (Nₒ) may be adjusted to the voltage level of the transfer node (Vₜ) by the auto-zeroing operation. Here, the voltage of the transfer node (Nₜ) after the first reset period (RST1) ends may be preset to be higher than the pixel signal (PS) corresponding to the reference signal.

When the ramping voltage (Vᵣₐₘₚ) generated by one ramping voltage generator 132 is directly supplied to the ADC 140, the voltage supplied to the ADC 140 in the second reset period (RST2) becomes lower than the pixel signal (PS) corresponding to the reference signal, so that the ADC 140 is unable to generate image data indicating the pixel signal (PS) corresponding to the reference signal. Accordingly, a method of using a plurality of ramping voltage generators may be considered, but the size of a circuit region and power consumption required for the ramping voltage generator may increase. In addition, ramping voltages are generated by different ramping voltage generators and are then transmitted to destinations through different paths. As a result, an unexpected deviation may occur, whereby noise may be introduced into the image data.

However, the ramp generator 130 based on some embodiments of the present disclosure can provide the ramp output signal (V_{ramp_out}) capable of generating image data representing the pixel signal (PS) in each of the LAG mode and HAG mode by using only one ramping voltage generator 132, resulting in reduction in the required circuit area and power consumption. In addition, the ramp output signal (V_{ramp_out}) corresponding to each of the LAG mode and the HAG mode may be generated based on the ramping voltage (Vᵣₐₘₚ) through one path, and the resultant ramp output signal (V_{ramp_out}) may be provided to an input capacitor of the ADC 140 through one path, thereby preventing a deviation and noise caused by a difference between paths.

After a predetermined time has elapsed, under control of the timing controller 170, the ramp generator 130 may output the ramp output signal (V_{ramp_out}) decreasing with a second slope from a voltage level at which the auto-zeroing operation was completed. Here, the magnitude of the second slope of the ramp output signal (V_{ramp_out}) in the second reset period (RST2) may be less than the magnitude of the first slope of the ramp output signal (V_{ramp_out}) in the first reset period (RST1).

The comparison data (CMP_OUT) may have a logic high level in a period in which the ramp output signal (V_{ramp_out}) is greater than the pixel signal (PS), and may have a logic low level in a period in which the ramp output signal (V_{ramp_out}) is less than the pixel signal (PS).

The counter enable signal (CNT_EN) may have a logic high level in a period in which the ramp output signal (V_{ramp_out}) has a second slope. The counter 144 may be activated in response to the counter enable signal (CNT_EN) having a logic high level, and the activated counter 144 may perform counting in a period in which the comparison data (CMP_OUT) has a logic high level, and may output a second reference value indicating the counting result as ADC data (ADC_OUT).

The second reference value may be a digital value obtained when the pixel signal (PS) corresponding to the reference signal is AD-converted in the HAG mode.

In the second signal period (SIG2), as the transfer signal (TG) temporarily has a logic high level, the pixel signal (PS) corresponding to the voltage of the floating diffusion region (FD) in which photocharges generated by the pixel (PX) are accumulated may be output from the pixel (PX). A voltage level of the pixel signal (PS) may be lowered in response to the amount of photocharges accumulated in the floating diffusion region (FD).

As the second signal period (SIG2) begins, the ramping voltage generator 132 is initialized so that the ramp output signal (V_{ramp_out}) returns to the voltage at which the auto-zeroing operation was performed in the second reset period (RST2), and after lapse of a predetermined time, the ramp generator 130 may output a ramp output signal (V_{ramp_out}) having a second negative (−) slope. In this case, the second slope of the ramp output signal (V_{ramp_out}) in the second signal period (SIG2) may be equal to the second slope of the ramp output signal (V_{ramp_out}) in the second reset period (RST2).

The comparison data (CMP_OUT) may have a logic high level or a logic low level according to the magnitude relationship between the ramp output signal (V_{ramp_out}) and the pixel signal (PS).

The counter 144 activated in response to the counter enable signal (CNT_EN) having a logic high level may perform counting in a period in which the comparison data (CMP_OUT) has a logic high level, and may output a second signal value indicating the counting result as ADC data (ADC_OUT).

The second signal value may be a digital value obtained when the pixel signal PS (i.e., image signal) corresponding to a voltage of the floating diffusion region (FD) in which photocharges generated by the pixel (PX) are accumulated is AD-converted in the HAG mode.

In the HAG mode, a value corresponding to a voltage difference between the image signal and the reference signal (i.e., a signal component from which reset noise has been removed) may be obtained by subtracting a second reference value from the second signal value.

In the first signal period (SIG1), while the ramp auto-zeroing signal (AZᵣ) has a logic high level, the ramp generator 130 may perform the auto-zeroing operation on the ramp output signal (V_{ramp_out}). In detail, the ramp generator 130 may perform the auto-zeroing operation in which the ramp switch (SWᵣ) is closed by the ramp auto-zeroing signal (AZᵣ) having a logic high level and a voltage level of the output node (Nₒ) is adjusted to a voltage level of the transfer node (Nₜ). In addition, as the ramping voltage generator 132 is initialized, the ramp output signal (V_{ramp_out}) may return to a voltage at a time point where the ramp output signal (V_{ramp_out}) starts to fall (or decrease) in the first reset period (RST1).

After a predetermined time has elapsed, the ramp generator 130 may output the ramp output signal (V_{ramp_out}) having a first negative (−) slope. Here, the first slope of the ramp output signal (V_{ramp_out}) in the first signal period (SIG1) may be equal to the first slope of the ramp output signal (V_{ramp_out}) in the first reset period (RST1).

The comparison data (CMP_OUT) may have a logic high level or a logic low level according to the magnitude relationship between the ramp output signal (V_{ramp_out}) and the pixel signal (PS).

The counter 144 activated in response to the counter enable signal (CNT_EN) having a logic high level may perform counting in a period in which the comparison data (CMP_OUT) has a logic high level, and may output a first signal value indicating the counting result as ADC data (ADC_OUT).

The first signal value may be a digital value obtained when the pixel signal (PS) corresponding to the voltage of the floating diffusion region (FD) in which photocharges generated by the pixel (PX) are accumulated is AD-converted in the LAG mode.

In the LAG mode, a value corresponding to a voltage difference between the image signal and the reference signal (i.e., a signal component from which reset noise has been removed) may be obtained by subtracting a first reference value from the first signal value.

A method for operating the image sensing device 100 described in FIG. 6 may include generating first image data by comparing the ramp output signal (V_{ramp_out}), which changes according to the first slope, with the pixel signal (PS) output from the pixel (PX) that senses the incident light; electrically connecting the output node (Nₒ), through which the ramp output signal (V_{ramp_out}) is output, to the gate of the ramp source follower transistor (SFᵣ) generating the ramp output signal (V_{ramp_out}); and generating second image data by comparing the ramp output signal (V_{ramp_out}), which changes according to the second slope, with the pixel signal (PS).

In some embodiments, the above-described method may be applied to each of the first reset period (RST1) and the second reset period (RST2). In this case, the pixel signal (PS) may correspond to the reference signal, the first image data may be the first reference value, and the second image data may be the second reference value.

In some other embodiments, the above-described method may be applied to each of the second signal period (SIG2) and the first signal period (SIG1). In this case, the pixel signal (PS) may correspond to the image signal, the first image data may be the second signal value, and the second image data may be the first signal value.

Although the embodiments of the present disclosure have disclosed examples of the ADC 140 configured to generate image data with two analog gains for convenience of description, other embodiments are also possible, and the technical ideas of the disclosed technology can also be applied to other cases in which image data is generated using three or more analog gains without departing from the scope or spirit of the present disclosure.

As is apparent from the above description, the ramp generation circuit, the image sensing device including the ramp generation circuit, and the method for operating the image sensing device based on some embodiments of the present disclosure can reduce the circuit area and power consumption required to implement the ramp generator configured to use a plurality of analog gains.

The embodiments of the present disclosure may provide a variety of effects capable of being directly or indirectly recognized.

Although a number of illustrative embodiments have been described, it should be understood that modifications and enhancements to the disclosed embodiments and other embodiments can be devised based on what is described and/or illustrated in the present disclosure.

What is claimed is:

1. A ramp generation circuit comprising:
a ramping voltage generator configured to generate a ramping voltage that changes according to a first slope or a second slope;
a blocking capacitor configured to transmit the ramping voltage to a transfer node;
a signal output unit configured to amplify a voltage of the transfer node to output a ramp output signal to an output node; and
a ramp switch configured to selectively connect the transfer node to the output node.

2. The ramp generation circuit according to claim 1, wherein the first slope is greater than the second slope.

3. The ramp generation circuit according to claim 1, wherein the ramping voltage generator includes:
a plurality of current transistors connected in parallel between a power-supply terminal and a generation node, at which the ramping voltage generator generates the ramping voltage; and
a variable load resistor connected between the generation node and a ground terminal and having a variable resistance value.

4. The ramp generation circuit according to claim 3, wherein the blocking capacitor is connected to the generation node and the transfer node.

5. The ramp generation circuit according to claim 1, wherein the blocking capacitor selectively transmits an alternating current (AC) component of the ramping voltage to the transfer node.

6. The ramp generation circuit according to claim 1, wherein the blocking capacitor transfers the ramping voltage to the transfer node such that a voltage of the transfer node is independent of a direct current (DC) component of the ramping voltage.

7. The ramp generation circuit according to claim 1, wherein the signal output unit includes a source follower transistor, a gate of which is connected to the transfer node and a source of which is connected to the output node.

8. The ramp generation circuit according to claim 7, wherein a drain of the source follower transistor is connected to a ground terminal.

9. The ramp generation circuit according to claim 1, wherein the ramp switch selectively connects the transfer node to the output node in response to a ramp auto-zeroing signal, which has a logic high level before a slope of the ramp output signal changes between the first and second slopes.

10. The ramp generation circuit according to claim 1, wherein:
the signal output unit is further configured to generate, based on the ramping voltage, the ramp output signal changing according to one of the first and second slopes, and
the signal output unit outputs the ramp output signal through a single path.

11. An image sensing device comprising:
a ramp generation circuit including:
a ramp source follower transistor configured to output a ramp output signal to an output node by amplifying a voltage of a transfer node, to which a ramping voltage changes according to a first slope or a second slope is applied; and
a ramp switch configured to selectively connect the transfer node to the output node; and
an analog-to-digital converter (ADC) configured to generate image data by comparing the ramp output signal with a pixel signal output from a pixel configured to sense an incident light.

12. The image sensing device according to claim 11, wherein the ADC includes:
a comparator configured to generate comparison data by comparing the ramp output signal with the pixel signal;
a first switch configured to selectively connect a non-inverting input terminal of the comparator to an inverting output terminal of the comparator;
a second switch configured to selectively connect an inverting input terminal of the comparator to a non-inverting output terminal of the comparator; and
a counter configured to generate the image data by counting the comparison data.

13. The image sensing device according to claim 12, wherein the first and second switches are further configured to adjust voltage levels of the non-inverting and inverting input terminals, respectively, for the comparator to compare the ramp output signal with the pixel signal.

14. The image sensing device according to claim 12, wherein the ADC further includes:
a first input capacitor connected between the output node and the non-inverting input terminal; and
a second input capacitor connected between the output node and the inverting input terminal.

15. The image sensing device according to claim 11, wherein the ramp switch selectively connects the transfer node to the output node in response to a ramp auto-zeroing signal, which has a logic high level before a slope of the ramp output signal changes between the first and second slopes.

16. The image sensing device according to claim 11, wherein:
the ramp source follower transistor is further configured to generate, based on the ramping voltage, the ramp output signal changing according to one of the first and second slopes, and
the ramp source follower transistor outputs the ramp output signal through a single path.

17. A method for operating an image sensing device, the method comprising:
generating first image data by comparing a ramp output signal, which changes according to a first slope, with a pixel signal output from a pixel configured to sense an incident light;
electrically connecting an output node, through which the ramp output signal is output, to a gate of a ramp source follower transistor configured to generate the ramp output signal; and
generating second image data by comparing the ramp output signal, which changes according to a second slope different from the first slope, with the pixel signal.

18. The method according to claim 17, wherein the first slope is greater than the second slope when the pixel signal is a reference signal generated in a state that a sensing node of the pixel is reset.

19. The method according to claim 17, wherein the first slope is less than the second slope when the pixel signal is an image signal generated in a state that photocharges generated by the pixel are accumulated in a sensing node of the pixel.

20. The method according to claim 17, further comprising setting, after the electrically connecting, a voltage level of the ramp output signal to be higher than a voltage level of the pixel signal.
